(19) United States
(12) Patent Application Publication
(10) Pub. No.: US 2026/0065969 A1
(43) Pub. Date: Mar. 5, 2026

(54) CLOCK TRANSMISSION CIRCUITRY FOR A MULTI-CHIP MEMORY DEVICE

(71) Applicant: Micron Technology, Inc., Boise, ID (US)

(72) Inventors: Kallol Mazumder, Dallas, TX (US); Harish Gadamsetty, Allen, TX (US); Guy S. Perry, IV, Plano, TX (US)

(21) Appl. No.: 19/222,729

(22) Filed: May 29, 2025

Related U.S. Application Data
(60) Provisional application No. 63/687,667, filed on Aug. 27, 2024.

(51) Int. Cl. G11C 11/4076

(52) U.S. Cl. CPC G11C 11/4076

(57) ABSTRACT

A memory device includes a first memory chip having first circuits configured to use a clock to perform memory operations and a first transmitter configured to transmit the clock. The memory device also includes a first local interconnect configured to receive the clock from the transmitter and a second memory chip that includes second circuits to use the clock to perform memory operations, a first receiver configured to receive the clock from the first local interconnect, and a second transmitter configured to transmit the clock. The memory device also includes a second local interconnect configured to receive the clock from the second transmitter and a third memory chip located in a stack above the second memory chip. The third memory chip includes third circuits configured to use the clock to perform memory operations, and a second receiver configured to receive the clock from the second local interconnect.

### CROSS-REFERENCE TO RELATED APPLICATION

This application claims priority to U.S. Provisional Application No. 63/687,667, filed Aug. 27, 2024, which is hereby incorporated by reference in its entirety.

### BACKGROUND

### Field of the Present Disclosure

Embodiments of the present disclosure relate generally to semiconductor devices (e.g., memory devices). More specifically, embodiments of the present disclosure relate to transmitting clocks between dies of the memory device using through-silicon vias (TSVs).

### Description of Related Art

Memory devices may include multiple chips in a stacked design. A clock may be intra-chip. However, as more chips are included in the stack, driving the chips becomes more complicated. For instance, if the chips all couple to a single TSV that spans the depth of the stack, each of the chips adds larger TSV parasitics that makes merely increasing the transmitter size of the base chip and/or the other chips impractical or impossible. This is true, because as the transmitter(s) are made larger, the TSV carrying the signal becomes more loaded with an increasingly occasion of diminishing returns. Instead of increasing transmitter(s) size the clock performance may have to be limited, especially for stacks that are relatively high (e.g., higher that 2 or 4 stacked chips).

Embodiments of the present disclosure may be directed to one or more of the problems set forth above.

### BRIEF DESCRIPTION OF THE DRAWINGS

FIG. 1 is a simplified block diagram illustrating certain features of a memory device having clock circuitry and multiple memory chips, according to an embodiment of the present disclosure;

FIG. 2 is a diagram of clock distribution circuitry of a stack of chips in the memory device of FIG. 1 using a single through-silicon via (TSV), according to an embodiment of the present disclosure;

FIG. 3 is a diagram of clock distribution circuitry of a stack of chips in the memory device of FIG. 1 using multiple local TSVs, according to an embodiment of the present disclosure;

FIG. 4 is a diagram of clock retuning circuitry of the clock distribution circuitry of FIG. 3 using a stack identifier to tune the clock by rank in the stack of chips of FIG. 3, according to an embodiment of the present disclosure; and

FIG. 5 is a flow diagram of a process for distributing a clock through multiple chips in a stack of a multiple-chip memory device, such as the memory device of FIG. 1, according to an embodiment of the present disclosure.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

As previously mentioned, clock transmission between chips of a stacked memory device may be passed through though-silicon vias (TSVs). If a TSV spans the depth of the stack and is used to connect all of the chips that have similar transmitters, the TSV is loaded with parasitics from the transmitters and/or other circuitry of each of the chips coupled to the TSV. This issue is exacerbated as the stacks are higher. Furthermore, the base chip (rank 0) that drives the clock through the TSV may be made larger to accommodate the larger TSV parasitics. However, this increased transmitter size would also impact the size of the transmitters of the non-rank 0 chips. Thus, as the transmitters are made larger, the parasitics get worse. For relatively short stacks (e.g., two-chip or four-chip high stacks), a larger transmitter may be sufficient to overcome the issues, but for larger stacks (e.g., more than four chips) the stack height and the single TSV may negatively impact clock performance. Instead of a monolithic TSV, multiple local TSVs may be used by transmitting the clock between ranks by transmitting from a first rank (e.g., rank 0) to a second rank (e.g., rank 1). This clock is then propagated to a next rank (e.g., rank 2) using a different local TSV. As discussed below, every (or all but one) rank of the stack receives a clock signal via a receiver and a first TSV (e.g., front side), buffers the clock, and retransmits the buffered clock internally and/or via second TSV (e.g., back side).

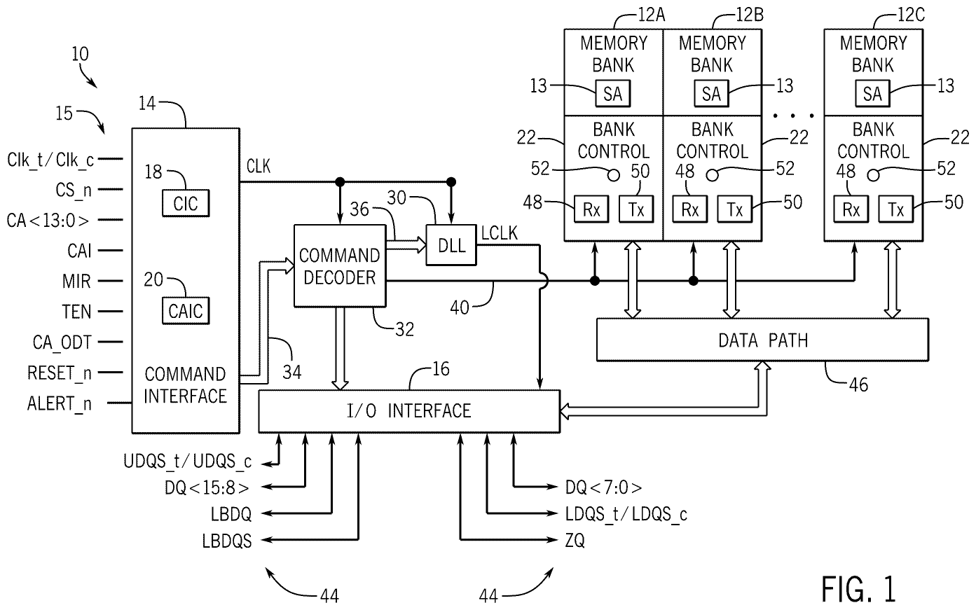

Turning now to the figures, FIG. 1 is a simplified block diagram illustrating certain features of a memory device 10. Specifically, the block diagram of FIG. 1 is a functional block diagram illustrating certain functionality of the memory device 10. In accordance with one embodiment, the memory device 10 may be a double data rate type five synchronous dynamic random-access memory (DDR5 SDRAM) device. Various features of DDR5 SDRAM allow for reduced power consumption, more bandwidth and more storage capacity compared to prior generations of DDR SDRAM. Furthermore, although the following discussion relates to DDR5 memory device, the disclosed scheme discussed herein may be likewise applied to any memory device of any suitable type that may include multiple chips in a stack. Indeed, the clock distribution scheme discussed herein may be applied to semiconductor devices beyond just memory devices for any semiconductor devices that may have chips in a stack that may distribute a clock.

The memory device 10, may include a number of memory banks 12 (individually referred to as memory banks 12A, 12B, and 12C). The memory banks 12 may be DDR5 SDRAM memory banks, for instance. The memory banks 12 may be provided on one or more chips/die (e.g., SDRAM chips) that are arranged on dual inline memory modules (DIMMS). For instance, the different chip may be stacked in a three-dimensional stack to form 3D RAM. Each DIMM may include a number of SDRAM memory chips (e.g., x8 or x16 memory chips), as will be appreciated. Each SDRAM memory chip may include one or more memory banks 12 and/or each of the memory banks 12 may be included on different memory chips. Additionally or alternatively, the memory device 10 represents a portion of a single memory chip (e.g., SDRAM chip) having a number of memory banks 12. For DDR5, the memory banks 12 may be further arranged to form bank groups and/or ranks. For instance, for an 8 gigabyte (Gb) DDR5 SDRAM, the memory chip may include 16 memory banks 12, arranged into 8 bank groups, each bank group including 2 memory banks in one or more memory ranks. For a 16 Gb DDR5 SDRAM, the memory chip may include 32 memory banks 12, arranged into 8 bank groups, each bank group including 4 memory banks, for instance. Various other configurations, organization and sizes of the memory banks 12 on the memory device 10 may be utilized depending on the application and design of the overall system.

The memory banks 12 and/or bank control blocks 22 include sense amplifiers 13. As previously noted, sense amplifiers 13 are used by the memory device 10 during read operations. Specifically, read circuitry of the memory device 10 utilizes the sense amplifiers 13 to receive low voltage (e.g., low differential) signals from the memory cells of the memory banks 12 and amplifies the small voltage differences to enable the memory device 10 to interpret the data properly.

The memory device 10 may include a command interface 14 and an input/output (IO) interface 16. The command interface 14 is configured to provide a number of signals (e.g., signals 15) from an external (e.g., host) device (not shown), such as a processor or controller. The processor or controller may provide various signals 15 to the memory device 10 to facilitate the transmission and receipt of data to be written to or read from the memory device 10.

As will be appreciated, the command interface 14 may include a number of circuits, such as a clock input circuit (CIC) 18 and a command address input circuit (CAIC) 20, for instance, to ensure proper handling of the signals 15. The command interface 14 may receive one or more clock signals from an external device. Generally, double data rate (DDR) memory utilizes a differential pair of system clock signals, the true clock signal Clk_t and the bar clock signal Clk_c. The positive clock edge for DDR refers to the point where the rising true clock signal Clk_t crosses the falling bar clock signal Clk_c, while the negative clock edge indicates that transition of the falling true clock signal Clk_t and the rising of the bar clock signal Clk_c. Commands (e.g., read command, write command, etc.) are typically entered on the positive edges of the clock signal and data is transmitted or received on both the positive and negative clock edges.

The clock input circuit 18 receives the true clock signal Clk_t and the bar clock signal Clk_c and generates an internal clock signal CLK. The internal clock signal CLK is supplied to an internal clock generator, such as a delay locked loop (DLL) circuit 30. The DLL circuit 30 generates a phase controlled internal clock signal LCLK based on the received internal clock signal CLK. The phase controlled internal clock signal LCLK is supplied to the IO interface 16, for instance, and is used as a timing signal for determining an output timing of read data. In some embodiments, the clock input circuit 18 may include circuitry that splits the clock signal into multiple (e.g., 4) phases. The clock input circuit 18 may also include phase detection circuitry to detect which phase receives a first pulse when sets of pulses occur too frequently to enable the clock input circuit 18 to reset between sets of pulses.

The internal clock signal(s)/phases CLK may also be provided to various other components within the memory device 10 and may be used to generate various additional internal clock signals. For instance, the internal clock signal CLK may be provided to a command decoder 32. The command decoder 32 may receive command signals from the command bus 34 and may decode the command signals to provide various internal commands. For instance, the command decoder 32 may provide command signals to the DLL circuit 30 over the bus 36 to coordinate generation of the phase controlled internal clock signal LCLK. The phase controlled internal clock signal LCLK may be used to clock data through the IO interface 16, for instance.

Further, the command decoder 32 may decode commands, such as read commands, write commands, mode-register set commands, activate commands, etc., and provide access to a particular memory bank 12 corresponding to the command, via the bus path 40. As will be appreciated, the memory device 10 may include various other decoders, such as row decoders and column decoders, to facilitate access to the memory banks 12. In one embodiment, each memory bank 12 includes the bank control block 22 which provides the necessary decoding (e.g., row decoder and column decoder), as well as other features, such as timing control and data control, to facilitate the execution of commands to and from the memory banks 12.

The memory device 10 executes operations, such as read commands and write commands, based on the command/address signals received from an external device, such as a processor. In one embodiment, the command/address bus may be a 14-bit bus to accommodate the command/address signals (CA<13:0>). The command/address signals are clocked to the command interface 14 using the clock signals (Clk_t and Clk_c). The command interface may include a command address input circuit 20, which is configured to receive and transmit the commands to provide access to the memory banks 12, through the command decoder 32, for instance. In addition, the command interface 14 may receive a chip select signal (CS_n). The CS_n signal enables the memory device 10 to process commands on the incoming CA<13:0> bus. Access to specific banks 12 within the memory device 10 is encoded on the CA<13:0> bus with the commands. For example, the bank control 22 may include clock circuitry that is used to transmit a clock from a base chip (e.g., memory bank 12A) to a targeted chip higher up in the stack of chips (e.g., memory bank 12B).

In addition, the command interface 14 may be configured to receive a number of other command signals. For instance, a command/address on die termination (CA_ODT) signal may be provided to facilitate proper impedance matching within the memory device 10. A reset command (RESET_n) may be used to reset the command interface 14, status registers, state machines and the like, during power-up for instance. The command interface 14 may also receive a command/address invert (CAI) signal which may be provided to invert the state of command/address signals CA<13:0> on the command/address bus, for instance, depending on the command/address routing for the particular memory device 10. A mirror (MIR) signal may also be provided to facilitate a mirror function. The MIR signal may be used to multiplex signals so that they can be swapped for enabling certain routing of signals to the memory device 10, based on the configuration of multiple memory devices in a particular application. Various signals to facilitate testing of the memory device 10, such as the test enable (TEN) signal, may be provided, as well. For instance, the TEN signal may be used to place the memory device 10 into a testmode for connectivity testing.

The command interface 14 may also be used to provide an alert signal (ALERT_n) to the system processor or controller for certain errors that may be detected. For instance, an alert signal (ALERT_n) may be transmitted from the memory device 10 if a cyclic redundancy check (CRC) error is detected. Other alert signals may also be generated. Further, the bus and pin for transmitting the alert signal (ALERT_n) from the memory device 10 may be used as an input pin during certain operations, such as the connectivity testmode executed using the TEN signal, as described above.

Data may be sent to and from the memory device 10, utilizing the command and clocking signals discussed above, by transmitting and receiving data signals 44 through the IO interface 16. More specifically, the data may be sent to or retrieved from the memory banks 12 over the data path 46, which includes a plurality of bi-directional data buses. Data IO signals, generally referred to as DQ signals, are generally transmitted and received in one or more bi-directional data busses. For certain memory devices, such as a DDR5 SDRAM memory device, the IO signals may be divided into upper and lower bytes. For instance, for a x16 memory device, the IO signals may be divided into upper and lower IO signals (e.g., DQ<15:8> and DQ<7:0>) corresponding to upper and lower bytes of the data signals, for instance.

To allow for higher data rates within the memory device 10, certain memory devices, such as DDR memory devices may utilize data strobe signals, generally referred to as DQS signals. The DQS signals are driven by the external processor or controller sending the data (e.g., for a write command) or by the memory device 10 (e.g., for a read command). For read commands, the DQS signals are effectively additional data output (DQ) signals with a predetermined pattern. For write commands, the DQS signals are used as clock signals to capture the corresponding input data. As with the clock signals (Clk_t and Clk_c), the DQS signals may be provided as a differential pair of data strobe signals (DQS_t and DQS_c) to provide differential pair signaling during reads and writes. For certain memory devices, such as a DDR5 SDRAM memory device, the differential pairs of DQS signals may be divided into upper and lower data strobe signals (e.g., UDQS_t and UDQS_c; LDQS_t and LDQS_c) corresponding to upper and lower bytes of data sent to and from the memory device 10, for instance.

An impedance (ZQ) calibration signal may also be provided to the memory device 10 through the IO interface 16. The ZQ calibration signal may be provided to a reference pin and used to tune output drivers and ODT values by adjusting pull-up and pull-down resistors of the memory device 10 across changes in process, voltage and temperature (PVT) values. Because PVT characteristics may impact the ZQ resistor values, the ZQ calibration signal may be provided to the ZQ reference pin to be used to adjust the resistance to calibrate the input impedance to known values. As will be appreciated, a precision resistor is generally coupled between the ZQ pin on the memory device 10 and GND/VSS external to the memory device 10. This resistor acts as a reference for adjusting internal ODT and drive strength of the IO pins.

In addition, a loopback data signal (LBDQ) and loopback strobe signal (LBDQS) may be provided to the memory device 10 through the IO interface 16. The loopback data signal and the loopback strobe signal may be used during a test or debugging phase to set the memory device 10 into a mode wherein signals are looped back through the memory device 10 through the same pin. For instance, the loopback signal may be used to set the memory device 10 to test the data output (DQ) of the memory device 10. Loopback may include both LBDQ and LBDQS or possibly just a loopback data pin. This is generally intended to be used to monitor the data captured by the memory device 10 at the IO interface 16. LBDQ may be indicative of a target memory device, such as memory device 10, data operation and, thus, may be analyzed to monitor (e.g., debug and/or perform diagnostics on) data operation of the target memory device. Additionally, LBDQS may be indicative of a target memory device, such as memory device 10, strobe operation (e.g., clocking of data operation) and, thus, may be analyzed to monitor (e.g., debug and/or perform diagnostics on) strobe operation of the target memory device.

As will be appreciated, various other components such as power supply circuits (for receiving external VDD and VSS signals), mode registers (to define various modes of programmable operations and configurations), read/write amplifiers (to amplify signals during read/write operations), temperature sensors (for sensing temperatures of the memory device 10), etc., may also be incorporated into the memory device 10. Accordingly, it should be understood that the block diagram of FIG. 1 is only provided to highlight certain functional features of the memory device 10 to aid in the subsequent detailed description. Furthermore, although the foregoing discusses the memory device 10 as being a DDR5 device, the memory device 10 may be any suitable device (e.g., a double data rate type 4 DRAM (DDR4), a ferroelectric RAM device, an HBM (high bandwidth memory) device, or a combination of different types of memory devices).

For the memory banks 12, the respective bank controls 22 include respective receivers 48, transmitters 50, and one or more TSVs 52. Although TSVs are discussed throughout, other interconnect techniques may be used with the clock distribution topology discussed herein. The receivers 48 are configured to receive clocks and/or other signals from the CIC 18 via the command interface 14, from a transmitter 50 of another memory bank 12, and/or from a transmitter 50 of the same memory bank 12. The transmitters 50 may transmit the clock and/or other signals to other chips and/or to its own corresponding receiver 48 to be used internally within the same corresponding memory bank 12.

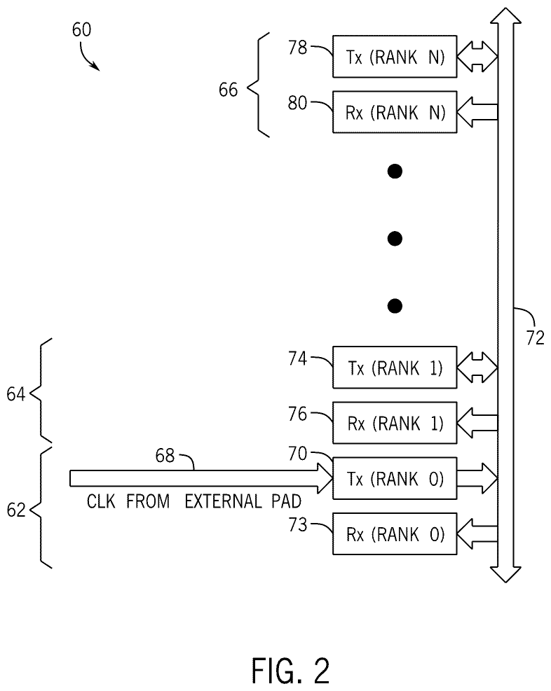

FIG. 2 is a diagram of clock distribution circuitry 60 of a stack of memory chips in the memory device 10. As illustrated, the clock distribution circuitry 60 is implemented in multiple ranks including rank 0 chip 62, rank 1 chip 64, and rank n chip 66. As such, the stack may include any suitable number of chips to include in a stack, such as 2, 3, 4, or more chips stacked in a vertical direction with a base chip being rank 0 chip 62 that receives the clock 68 from an external pad (e.g., from the CIC 18 via the command interface 14). As previously noted, each rank includes its own respective receiver and transmitter for distributing clocks. For instance, the rank 0 chip 62 includes a transmitter 70 that transmits the clock 68 via a through-silicon via (TSV) 72 to the rank 1 chip 64 and the rank n chip 66. The rank 0 chip 62 also includes a receiver 73 that may receive data from the TSV 72 and/or may receive the clock 68 from the transmitter 70 and/or the clock 68 from the external pad to be used internally within the memory banks of the rank 0 chip 62. The rank 1 chip 64 includes a transmitter 74 coupled to the TSV 72. The rank 1 chip 64 also includes a receiver 76 that may receive data and/or the clock 68 from the TSV 72 and/or may receive the clock 68 from the transmitter 74 to be used internally within the memory banks of the rank 1 chip 64. The rank n chip 66 includes a transmitter 78 coupled to the TSV 72. The rank n chip 66 also includes a receiver 80 that may receive data and/or the clock 68 from the TSV 72 and/or may receive the clock 68 from the transmitter 78 to be used internally within the memory banks of the rank n chip 66.

As previously mentioned, the TSV 72 spans all of the chips meaning that the receivers 73, 76, and 80 along with the transmitters 70, 74, and 78 load the TSV 72. Furthermore, the non-rank 0 chips (e.g., rank 1 chip 64, rank n chip 66) may have inactive transmitters (e.g., transmitters 74 and 78) that do not transmit the clocks in at least some situations but still load the TSV 72. This loading of the TSV 72 increases as the stack height increases with the addition of more transmitters along the TSV 72. This loading decreases fidelity. Increasing the size of the transmitters to overcome this loading increases the load and degrades the signal more. Thus, increasing transmitter size may be impractical or impossible for stacks above a certain number (e.g., 2-4) of chips.

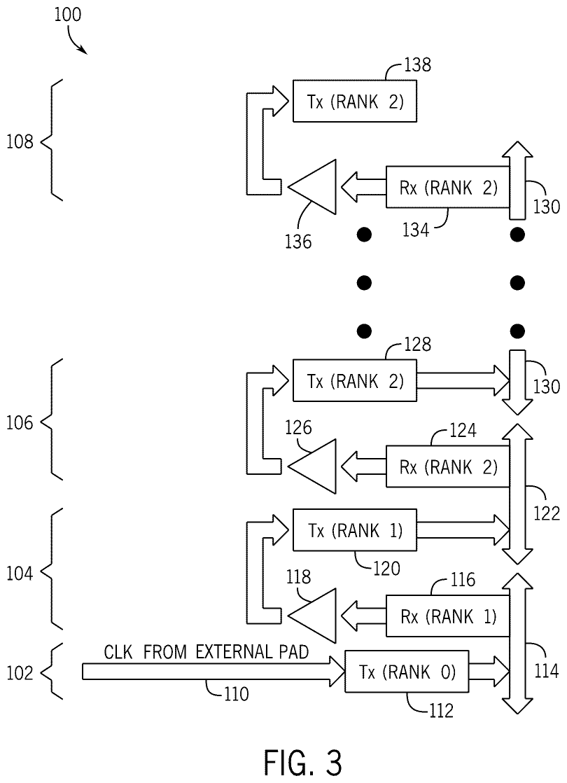

Instead of a single through TSV spanning all of the chips, the memory device 10 may use multiple local TSVs. For instance, a local TSV may span only a subset of the chips in a stack, such as 2, 3, 4, or more of a total number n of chips in the stack. FIG. 3 is a diagram of clock distribution circuitry 100 that spans a rank 0 chip 102, a rank 1 chip 104, a rank 2 chip 106, and a rank n chip 108. The number of chips may include any suitable number, such as 2, 3, 4, or more chips stacked in a single stack of the memory device 10. The rank 0 chip 102 acts as a base chip for the stack and receives a clock 110 from the external pad (e.g., from a host device) via the CIC 18 via command interface 14. In some embodiments, this clock 110 may be received at a receiver of the rank 0 chip 102. Regardless of how the clock 110 is received, a transmitter 112 of the rank 0 chip 102 transmits the clock 110 to the rank 1 chip 104 via a local TSV 114 (e.g., front side TSV). As previously noted, a local TSV may extend between only a subset of the chips of the stack. In the illustrated embodiment, each local TSV spans only two chips, but in some embodiments, the local TSVs may span more than 2 but less than the entire span (e.g., less than 4 chips) to at least partially limit loading on the TSVs. Furthermore, in some embodiments, the local TSVs may each span the same number of chips (e.g., 2, 3, 4, or more) or different local TSVs may span different numbers of chips. For instance, one TSV may span two chips in a stack while another local TSV spans three other chips in the stack.

The local TSV 114 couples to a receiver 116 of the rank 1 chip 104 that receives the transmitted clock 110 from the transmitter 112. The transmitted clock 110 is then passed to a buffer 118 of the rank 1 chip 104 that enables the rank 1 chip 104 to provide the clock 110 to its own transmitter 120 without excessively loading the local TSV 114. In some embodiments, the buffer 118 and/or the receiver 116 may be combined into a single element that receives and buffers the clock 110. The transmitter 120 then transmits the clock 110 as a retransmitted clock through a local TSV 122 (e.g., a back side TSV) to the rank 2 chip 106.

The local TSV 122 couples to a receiver 124 of the rank 2 chip 106 that receives the retransmitted copy of the clock 110 from the transmitter 120. The retransmitted version of the clock 110 is then passed to a buffer 126 of the rank 2 chip 106 that enables the rank 2 chip 106 to provide the clock 110 to its own transmitter 128 without excessively loading the local TSV 122. The transmitter 128 then transmits the clock 110 as a retransmitted clock through a local TSV 130 (e.g., a front side TSV) and so on, in a daisy-chained fashion, eventually to the rank n chip 108.

A local TSV 131 couples to a receiver 134 of the rank n chip 108 that receives the retransmitted copy of the clock 110 from the transmitter 128. The local TSV 131 may be the same as the local TSV 130 when the stack has only 4 chips. The retransmitted version of the clock 110 is then passed to a buffer 136 of the rank n chip 108 that enables the rank n chip 108 to provide the clock 110 to its own transmitter 138 without excessively loading the local TSV 122. In some embodiments, the transmitter 138 may be inactive. Additionally or alternatively, the transmitter 138 may remain active to enable the clock 110 to enter the chip and be used by the memory banks 12 of the rank n chip 108. As may be appreciated, the inclusion of the buffers 118, 126, and 136 may introduce some delay for each rank due to each receipt and broadcast from lower ranks that rebroadcast the clock. Even though the amount of delay is progressive with greater delay as the clock progresses up the stack, the amount of delay is known, and the local TSVs may each have much better clock characteristics than those through the TSV 72 that spans the whole stack. Furthermore, the amount of delay added by the buffers may be mitigated by returning the clock 110 at each rank by factoring such delays into other delays used in the memory device 10.

In the memory device 10, the bank control 22 delays the clock to match arriving commands. This delay is due to the fact that every received command on each chip is qualified with a chip identifier (ChipID). The delay mechanism involves capturing the external ChipID as part of the CA bits. The command decoder 32 then decodes the command and matches the ChipID to a stack identifier (StackID) that is a unique identifier for each die in the stack. Traditionally, this StackID may be configured at powerup. The delay added to the clock 110 mimics the amount of time that such match detection logic circuitry uses to complete such matching. However, this amount of delay may be considerably longer than any cumulative buffer delay introduced by the retransmission of the clock 110 using the buffers. Accordingly, each rank may reduce this match mimic delay by an amount of known buffer delay for the respective rank to cause the clocks to toggle at the same time between the ranks regardless of the amount of buffer delay. In some embodiments, this adjustment may be made only to the clock signal without impacting any other signals (e.g., data, etc.).

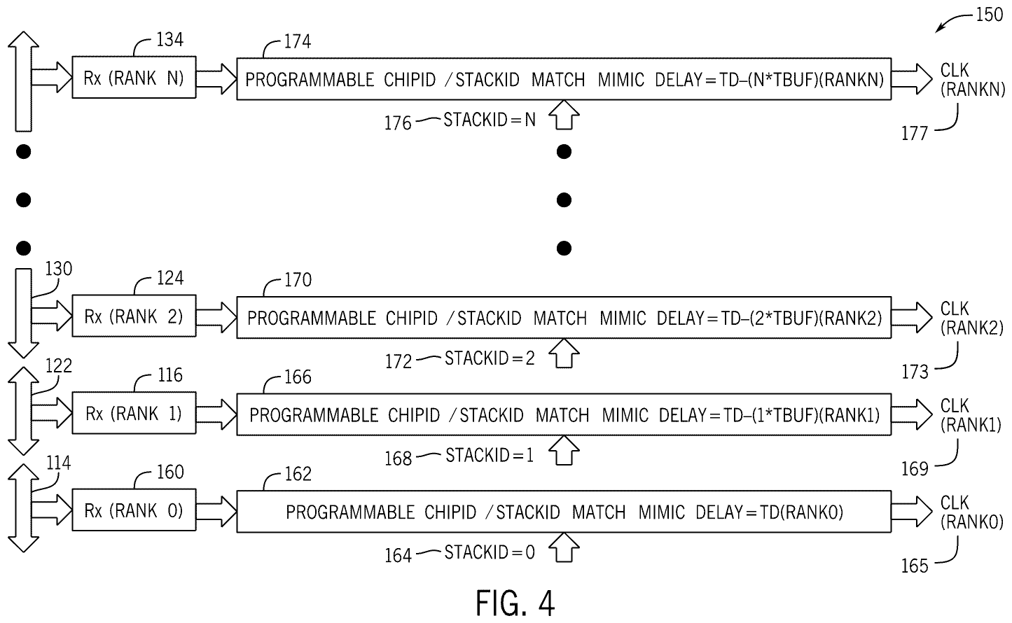

FIG. 4 is a block diagram of clock retuning circuitry 150 that may be part of the clock distribution circuitry 100 of FIG. 3 that may retune the clock 110 based on a stack identifier identifying ranks of the chips. As illustrated, the clock retuning circuitry 150 spans the rank 0 chip 102, the rank 1 chip 104, the rank 2 chip 106, and the rank n chip 108. The clock retuning circuitry 150 retunes the versions of the clock 110 received by the receivers 160, 116, 124, and 134. The clock retuning circuitry 150 includes delay circuitry in each rank that is configured to offset a mimic delay by an amount of expected buffer delay. Although there may be minor differences between delays in the different buffers by process corners, the delays due to buffering will be relatively the same (e.g., within a cycle of the clock 110).

In the rank 0 chip 102, the clock retuning circuitry 150 includes delay circuitry 162 that delays the clock 110 by an amount of delay mimicking to the amount of time (tD) used to complete matching between the ChipID and the StackID using the command decoder 32 and/or bank control 22. The delay amount in the delay circuitry 162 may be programmable. The amount of delay is set using a StackID (e.g., 0) 164 identifying the rank 0 chip 102. The amount of delay introduced in the programmable delay circuitry 162 is equal to tD since no buffer delay is added to the clock 110 in the rank 0 chip 102. Thus, the received clock 110 is delayed by tD to output clk (rank0) 165 for use in the rank 0 chip 102.

In the rank 1 chip 104, the clock retuning circuitry 150 includes delay circuitry 166 that delays the clock 110 (transmitted clock from the rank 0 chip 102) by tD minus the amount of delay in buffering the clock 110 in the rank 1 chip 104 based on a StackID (e.g., 1) 168 identifying the rank 1 chip 104. Specifically, since only a single buffer is used in the rank 1 chip 104, the amount of tD is only offset by a single buffer delay (tBUF). Thus, the transmitted version of the clock 110 is delayed by tD minus tBUF to output clk (rank1) 169 for use in the rank 1 chip 104.

In the rank 2 chip 106, the clock retuning circuitry 150 includes delay circuitry 170 that delays the clock 110 (retransmitted clock from the rank 1 chip 104) by tD minus the amount of delay in buffering the clock 110 in the rank 1 chip 104 and the rank 2 chip 106 based on a StackID (e.g., 2) 172 identifying the rank 2 chip 106. Specifically, since a single buffer is used in the rank 1 chip 104 and a single buffer is used in the rank 2 chip 106, the amount of tD is offset by two times tBUF. Thus, the retransmitted version of the clock 110 is delayed by tD minus tBUF*2 to output clk (rank2) 173 for use in the rank 2 chip 106.

In the rank n chip 108, the clock retuning circuitry 150 includes delay circuitry 174 that delays the clock 110 (retransmitted clock from the rank 2 chip 106) by tD minus the amount of delay in buffering the clock 110 in the rank 1 chip 104, the rank 2 chip 106, and the rank n chip 108 based on a StackID (e.g., n) 176 identifying the rank n chip 108. Specifically, since a single buffer is used in n ranks before being used in the rank n chip 108, the amount of tD is offset by n times tBUF. Thus, the retransmitted version of the clock 110 is delayed by tD minus tBUF*n to output clk (rankn) 177 for use in the rank n chip 108. As previously discussed, the clks for the different ranks have the same timings (e.g., on a same clock cycle) on local chip destinations.

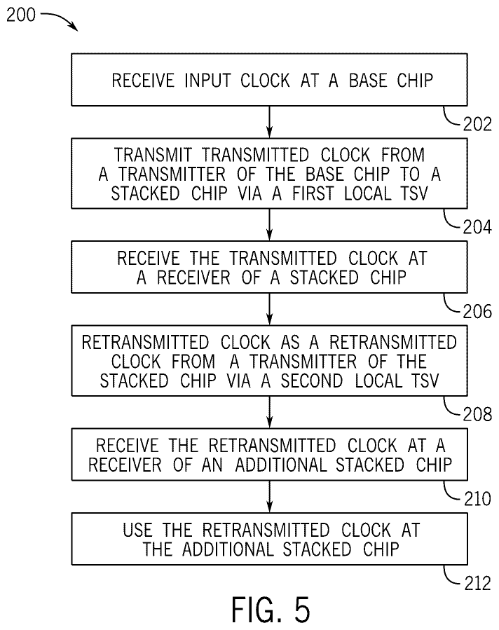

FIG. 5 is a flow diagram of a process 200 for distributing a clock through multiple chips in a stack of the memory device 10. As illustrated, the memory device 10 receives an input clock (e.g., clock 110) at a base chip (e.g., rank 0 chip 102) (block 202). The transmitter 112 of the base chip transmits a transmitted clock based on the received clock to a stacked chip (e.g., rank 1 chip 104) via a first location TSV (e.g., local TSV 114) (block 204). The receiver 116 of the stacked chip receives the transmitted clock (block 206). In some embodiments, receiving the transmitted clock includes buffering the transmitted clock in a buffer (e.g., buffer 118). The transmitter 120 of the stacked chip retransmits the clock as a retransmitted clock via a second local TSV (block 208). The receiver 128 of an additional stacked chip (e.g., rank 2 chip 106) receives the retransmitted clock (block 210). The memory bank of the additional stacked chip uses the retransmitted clock at the additional stacked chip to perform a memory operation (block 212). In some embodiments, using the retransmitted clock may include retuning the retransmitted clock based on a stack identifier of a respective chip as discussed previously in relation to FIG. 4 above.

With the foregoing in mind, the discussion herein makes clear that local TSVs with a daisy-chained buffer topology provides a reliable clock distribution scheme across even relatively high stacks of chips by avoiding or limiting loading from inactive drivers on a TSV that spans the stack. Due to this topology, a clock transmitter suitable for smaller stacks of chips with a single TSV may be used. Indeed, clock transmitter sizes may be downsized on existing memory devices without signal degradation since the clock only needs to be transmitted between a small number (e.g., 2-4) chips. The buffering topology adds delay that may be at least partially mitigated by at least partially reducing mimicked delays of matching logic that exists in memory devices.

While the present disclosure may be susceptible to various modifications and alternative forms, specific embodiments have been shown by way of example in the drawings and have been described in detail herein. However, it should be understood that the present disclosure is not intended to be limited to the particular forms disclosed. Rather, the present disclosure is intended to cover all modifications, equivalents, and alternatives falling within the spirit and scope of the present disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

1. A memory device, comprising:
a first memory chip configured to receive a clock and comprising:
a first plurality of circuits configured to control timing for memory operations based on the clock;
a first transmitter configured to transmit the clock;
a first local interconnect configured to receive the clock from the first transmitter;
a second memory chip located in a stack above the first memory chip, comprising:
a second plurality of circuits configured to control timing for memory operations based on the clock;
a first receiver configured to receive the clock from the first local interconnect; and
a second transmitter configured to transmit the clock;
a second local interconnect configured to receive the clock from the second transmitter; and
a third memory chip located in the stack above the second memory chip, comprising:
a third plurality of circuits configured to control timing for memory operations based on the clock;
a second receiver configured to receive the clock from the second local interconnect.

2. The memory device of claim 1, comprising a clock input circuit configured to receive the clock from a host device and transmit the clock to the first memory chip.

3. The memory device of claim 2, wherein the clock input circuit comprises a pin configured to receive the clock from the host device.

4. The memory device of claim 1, wherein the first local interconnect comprises a first TSV connecting only the first memory chip to the second memory chip, and the second local interconnect comprises a second TSV connecting only the second memory chip to the third memory chip.

5. The memory device of claim 1, wherein the third memory chip comprises a third transmitter configured to transmit the clock to the third plurality of circuits.

6. The memory device of claim 1, comprising a third local interconnect, wherein the third memory chip comprises a third transmitter configured to transmit the clock to the third local interconnect.

7. The memory device of claim 6, comprising:
a fourth memory chip located in a stack above the third memory chip, comprising:
a fourth plurality of circuits; and
a third receiver configured to receive the clock from the third local interconnect.

8. The memory device of claim 7, wherein the first local interconnect comprises a first TSV, the second local interconnect comprises a second TSV, and the third local interconnect comprises a third TSV.

9. The memory device of claim 8, wherein the first TSV interconnects the first memory chip with the second memory chip, the second TSV interconnects the second memory chip and the third memory chip, and the third TSV interconnects the third memory chip and the fourth memory chip.

10. The memory device of claim 7, wherein the second memory chip comprises a first buffer configured to buffer the clock before being used by the second plurality of circuits and before transmission to the second local interconnect, and the third memory chip comprises a second buffer configured to buffer the clock before being used by the third plurality of circuits.

11. The memory device of claim 10, wherein the second memory chip comprises first clock tune circuitry configured to delay the clock in the second memory chip by a first amount of time based at least in part on a first stack identifier of the second memory chip and a mimicked duration of matching a stack identifier to a chip identifier received with a memory command.

12. The memory device of claim 11, wherein the third memory chip comprises second clock tune circuitry configured to delay the clock in the third memory chip by a second amount of time based at least in part on a second stack identifier of the third memory chip and the mimicked duration of matching the stack identifier to the chip identifier received with the memory command, wherein the first amount of time and the second amount of time are different.

13. A method for distributing a clock in a multi-chip memory device, comprising:
receiving an input clock at a base chip of a stack of the multi-chip memory device;
transmitting a transmitted clock based on the input clock, wherein transmitting is performed from a transmitter of the base chip to a stacked chip via a first local TSV;
receiving the transmitted clock at a receiver of the stacked chip;
retransmitting the transmitted clock as a retransmitted clock from a transmitter of the stacked chip via a second local TSV;
receiving the retransmitted clock at a receiver of an additional stacked chip; and
using the retransmitted clock at the additional stacked chip.

14. The method of claim 13, wherein using the retransmitted clock comprises performing a memory operation in memory cells of the additional stacked chip.

15. The method of claim 13, wherein using the retransmitted clock comprises delaying the retransmitted clock in the additional stacked chip by a first amount of delay based at least in part on a first stack identifier of the additional stacked chip and on a mimicked duration of matching the first stack identifier to a chip identifier received with a memory command.

16. The method of claim 15, comprising wherein the first amount of delay comprises the mimicked duration minus buffer delays through a buffer of the additional stacked chip and through a buffer of the stacked chip.

17. The method of claim 16, comprising delaying the transmitted clock in the stacked chip by a second amount of delay based at least in part on a second stack identifier of the stacked chip and on the mimicked duration, wherein the first amount of delay and the second amount of delay are different.

18. The method of claim 17, wherein the second amount of delay comprises the mimicked duration minus buffer delays through the buffer of the stacked chip.

19. A memory device, comprising:
clock input circuit configured to receive a clock from a host device;
clock distribution circuitry comprising:
a plurality of local TSVs;
a transmitter in each of a plurality of memory chips in a stack of the memory device and in a base chip of the stack and configured to transmit a respective clock to a respective local TSV of the plurality of local TSVs;
a receiver in each of the plurality of memory chips configured to receive a respective clock from a respective local TSV; and
a buffer in each of the plurality of memory chips configured to buffer a respective clock from a respective receiver before retransmission via a respective transmitter.

20. The memory device of claim 19, wherein the memory device comprises clock tuning circuitry comprising delay circuitry in each of the plurality of memory chips and in the base chip, wherein each of the delay circuitries is configured to apply a delay to a respective clock based on a respective stack identifier and an amount of time mimicking a matching duration where the respective stack identifier is matched to a chip identifier received with a memory command.
